(19) United States
(12) Patent Application Publication
(10) Pub. No.: US 2023/0237224 A1
(43) Pub. Date: Jul. 27, 2023

(54) METHOD AND DEVICE FOR DETERMINING A STATE EVOLUTION OF A REAL SYSTEM

(71) Applicant: Deutsches Zentrum für Luft-und Raumfahrt e.V., Bonn (DE)

(72) Inventors: Christoph RÄTH, Eching (DE); Sebastian BAUR, München/Munich (DE)

(21) Appl. No.: 18/002,281

(22) PCT Filed: Jun. 23, 2021
(86) PCT No.: PCT/EP2021/067229

§ 371 Date: Dec. 19, 2022

(30) Foreign Application Priority Data
Jun. 26, 2020 (DE) 10 2020 116 934.5

(51) Int. Cl. G06F 30/27

(52) U.S. Cl. CPC G06F 30/27

(57) ABSTRACT

The invention relates to a method for determining a state evolution of a real system with a plurality N of degrees of freedom, comprising the following steps: determining states for each of the plurality N of degrees of freedom up to a time t₀, wherein the determining of states for each of the plurality N of degrees of freedom is carried out by measuring corresponding state variables of the real system; selecting a degree of freedom f from the plurality N of degrees of freedom; determining a measure of similarity between the selected degree of freedom f and each other degree of freedom of the plurality N of degrees of freedom of the real system for the determined states; determining a selection M of degrees of freedom from the plurality N of degrees of freedom based on the measure of similarity; and determining the state evolution of measured states for the selected degree of freedom f based on the selection M of degrees of freedom.

The present invention relates to a method and a device for determining a state evolution of, in particular, measured states of a real system.

Real systems typically have a high number of degrees of freedom. Such a real system may be, for example, a thermodynamic system, such as, for example, the weather, the combustion chamber of internal combustion engines, a fluidic system, such as, for example, a flow in a given topography, or a movement system, such as, for example, the movement of persons in a given environment or the like. Here, the real system can be characterized by measured variables, such as, for example, temperature, pressure, voltage, position, concentration or the like, wherein a number of degrees of freedom is selected for characterization. The state of the real system is defined as the set of all relevant measured variables at a predefined time.

The determination of the evolution of these measured states of the real system provides valuable information about the behavior of the real system.

From prior art it is known to determine the state evolution of a real system by trained systems, the trained systems or networks are trained on the basis of a plurality of measured states of the real systems. Using this trained system, a state evolution of the real system is then to be determined under different starting conditions or for a period posterior to the period of the plurality of measured states.

Real systems with a large number of degrees of freedom can be calculated only with difficulty and with great computational effort, since individual degrees of freedom interact with one another and thus the evolution of the degrees of freedom have effects on one another. As a result, the calculation of these real systems is complex and requires large computational capacities.

It is an object of the present invention to provide a method for determining a state evolution for a real system, which is easier to calculate and has a reduced demand on the necessary computational power.

The object is achieved with the method according to claim 1 and the device according to claim 12.

The present method for determining a state evolution of a real system with a plurality N of degrees of freedom comprises the following steps:
a) determining states for each of the plurality N of degrees of freedom up to a time t₀, wherein the determining of states for each of the plurality N of degrees of freedom is carried out in particular by measuring corresponding state variables of the real system;
b) selecting a degree of freedom f from the plurality N of degrees of freedom;
c) determining a similarity A_{f} between the selected degree of freedom f and a plurality of other degrees of freedom of the plurality N of degrees of freedom of the real system for the determined states;
d) determining a selection M_{f} of degrees of freedom from the plurality N of degrees of freedom based on the similarity A_{f}; and
e) determining the state evolution for the selected degree of freedom f based on the selection M_{f} of degrees of freedom.

For example, the determination of states for each of the plurality N of degrees of freedom is performed by measuring the corresponding state variables of the real system. The state variables are, for example, temperature, pressure, concentration, position, voltage, current or any other measurable variable. Therein, states of the real system for a predefined time are the set of all state variables at this time for the respective degree of freedom. Here, each degree of freedom of the system is represented by at least one state variable.

Then, at least one degree of freedom f is selected from the plurality N of degrees of freedom.

For this at least one degree of freedom f, a similarity A_{f} is determined between the at least one selected degree of freedom f and another degree of freedom of the plurality N of the degrees of freedom of the system without the at least one degree of freedom f for the previously determined states. The similarity A_{f} describes the similarity of the state evolution up to the time t₀ between the at least one degree of freedom f and the other degree of freedom of the plurality N of degrees of freedom of the system. Therein, the at least one selected degree of freedom f may refer to another state variable than the compared degree of freedom. The temporal development of the compared degrees of freedom is essential to the evaluation of the similarity. Thereafter, for several other degrees of freedom of the plurality N of degrees of freedom, a similarity between the selected degree of freedom f and the corresponding other degree of freedom of the plurality N of degrees of freedom of the system is also determined. By determining the similarity, it is thus possible to find degrees of freedom from the plurality N of degrees of freedom, whose temporal development or time series is similar to that of the at least one selected degree of freedom f or are correlated with the same. Here, no evident connection has to exist between the at least one selected degree of freedom f and the similar degree of freedom that shows a similarity A_{f}. In particular, a local proximity is not required between the at least one degree of freedom f and the degree of freedom determined based on the similarity A_{f}.

Thereafter, a selection M_{f} of degrees of freedom from the plurality N of degrees of freedom of the real system is determined based on the similarity A_{f}. Here, M_{f} is a subset of the plurality N and thus, M_{f} is smaller than N. In particular, M_{f} includes the degrees of freedom that have the greatest similarity to the at least one selected degree of freedom.

Thereafter, the state evolution for the selected degree of freedom f is determined based on the selection M_{f} of degrees of freedom.

Thereby, the complexity in determining the state evolution for the selected degree of freedom f is reduced. In particular, it is not necessary to consider all degrees of freedom of the plurality N of the real system, but only such degrees of freedom are considered in determining the state evolution for the at least one selected degree of freedom f, which show a corresponding similarity A_{f}. Here, it may be assumed that degrees of freedom with a high similarity to the selected degree of freedom f have an influence on the state evolution of the degree of freedom f and correlate with each other in some way and thus have to be considered when determining the state evolution for the at least one selected degree of freedom f. Due to the reduction of the complexity in determining the state evolution for the at least one selected degree of freedom f, the demands on the computational capacities are reduced, so that an efficient determination of the state evolution is guaranteed even for high-dimensional real systems with a large number N of degrees of freedom.

Preferably, the similarity A_{f} between the at least one selected degree of freedom f and each of the degrees of freedom of the plurality N of degrees of freedom of the real system for the determined states is determined and thus each degree of freedom is considered in determining the selection M_{f}.

Preferably, more than one degree of freedom f is selected. Thus, these several degrees of freedom f are combined/clustered and subsequently a selection M_{f} is jointly determined for these several degrees of freedom. Thereby, a further reduction in complexity can be achieved.

Preferably, the above mentioned steps b) to d) are repeated for each degree of freedom of the plurality N of degrees of freedom for determining the degrees of freedom to be considered in determining the state evolution of the, in particular, measured states for the entire real system. Thus: f=1, . . . ,N, where for each of the respective selected degrees of freedom f, a selection M_{f} of degrees of freedom is determined from the plurality N without f based on the respective similarity A_{f}. Hence, the complexity of the determination of the state evolution of the, in particular, measured states for the entire real system is reduced, whereby the demands on the computational capacities are reduced significantly. Thus, a determination of the state evolution is possible even for high-dimensional real systems having a large number of degrees of freedom.

Preferably, the number of degrees of freedom of the plurality N of degrees of freedom is higher than 10, in particular higher than 100, and preferably higher than 1000. With such a large number of degrees of freedom, a simultaneous consideration of all degrees of freedom in determining the state evolution of the respective degrees of freedom is not possible and exceeds the computational capacity of present day computers. However, due to the present invention, a suitable reduction in complexity can be effected, so that even for real systems having more than 10, more than 100 and in particular more than 1000 degrees of freedom, it is possible to determine a state evolution for the entire system.

Preferably, the number of degrees of freedom in the selection Mf is less than 1000, preferably less than 100 and particularly preferred less than 10. Thus, a reduction in complexity and in particular of the number of degrees of freedom to be considered is achieved.

Preferably, the number of degrees of freedom in the selection M_{f} is the same for each of the selected degrees of freedom f. As an alternative, for each of the selected degrees of freedom f in the selection M_{f}, a different number of degrees of freedom can be selected for determining the state evolution for the selected degree of freedom f, so that M_{f}, f=1, . . . ,N are each different.

Preferably, the degrees of freedom are sorted by similarity, wherein the selection M_{f} respectively includes the degrees of freedom with the greatest similarity.

Preferably, the similarity is determined by a measure of similarity that quantifies the similarity between two degrees of freedom.

Preferably, the number of degrees of freedom in the selection M_{f} is determined by a predefined limit value for the measure of similarity. Thus, all degrees of freedom are included in the selection M_{f}, for which the measure of similarity exceeds a predefined limit value.

Preferably, the number of degrees of freedom in the selection M_{f} is predefined. As such, a fixed number may be predefined for the number of degrees of freedom in the selection M_{f}. In particular, when sorting the degrees of freedom with decreasing similarity, the first r degrees of freedom are selected for the selection M_{f}, where r is the number of degrees of freedom in the selection M_{f}. Of course, the degrees of freedom may be sorted by ascending similarity, with the last r degrees of freedom being selected accordingly.

Preferably, the similarity A_{f} is determined by a cross-correlation or mutual information. Other measures of similarity may also be used to determine a similarity between the selected degree of freedom f and the respective other degree of freedom from the plurality N of degrees of freedom of the real system.

Preferably, the determination of the state evolution is performed using a recurrent neural network, in particular by means of reservoir computing.

Preferably, the recurrent neural network is trained based on the determined states for each of the plurality N of degrees of freedom up to a time t₀.

Preferably, the real system is a thermodynamic system, a fluidic system, a flow system, EEG currents or another complex system with a plurality of degrees of freedom or the like. Thus, it is possible to determine states of these real systems without the need for a complex measurement.

Preferably, a control variable is determined to control the real system, depending on the determined state evolution. In particular, the control variable calculated in dependence on the determined state evolution, can be used to return the real system to a predefined target state again. Thereby, a simple feedback mechanism can be created which allows to suitably adapt the current state of the real system and thereby, for example, to convert undesired states of the real system into a desired target state and/or to continuously adapt the real system by means of a recursive feedback mechanism by periodically determining the state evolution and controlling the real system and by a correspondingly determined control variable.

According to the invention, a device is provided that comprises a processor and a computer-readable storage medium, the device being configured to perform the method with the above steps.

In the following, the invention is described in more detail by means of preferred embodiments with reference to the accompanying drawings.

In the drawings:

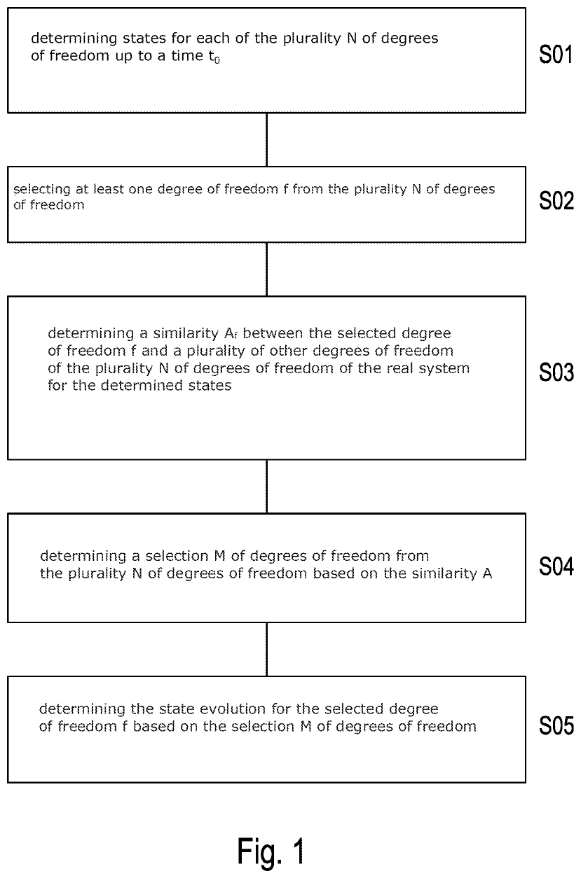

FIG. 1 shows a first embodiment of the method according to the invention, and

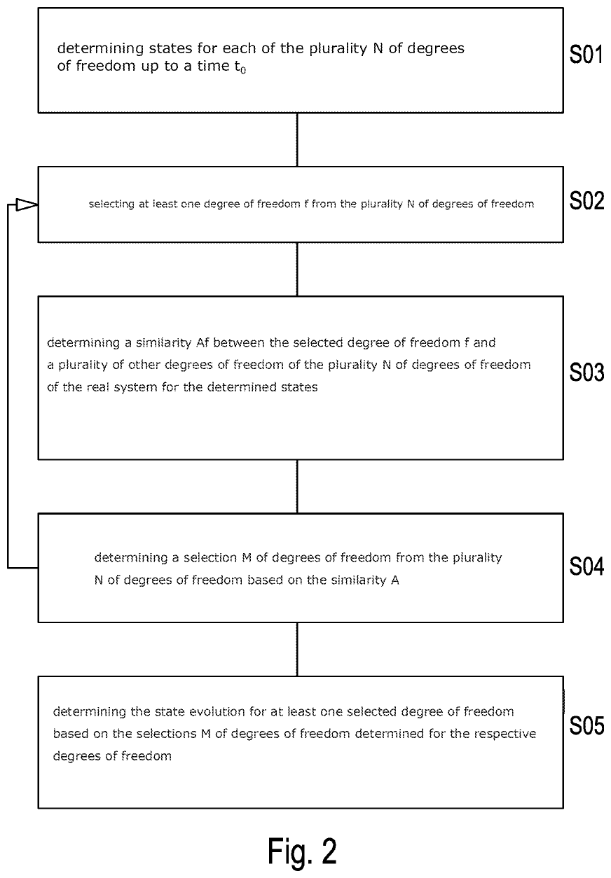

FIG. 2 shows a second embodiment of the method according to the invention.

In a first embodiment of the method according to the invention shown in FIG. 1, the method comprises the following steps:

Step S01: determining states for each of the plurality N of degrees of freedom up to a time t₀, wherein, in particular, the determining of states for each of the plurality N of degrees of freedom is carried out by measuring corresponding state variables of the real system;

Step S02: selecting at least one degree of freedom f from the plurality N of degrees of freedom;

Step S03: determining a similarity A_{f} between the at least one selected degree of freedom f and a plurality of other degrees of freedom of the plurality N of degrees of freedom without the selected degree of freedom f of the real system for the determined states;

Step S04: determining a selection M_{f} of degrees of freedom from the plurality N of degrees of freedom based on the similarity A_{f}; and

Step S05: determining the state evolution for the at least one selected degree of freedom f based on the selection Mf of degrees of freedom.

In step S01, states are detected based on the real system for each of the plurality N of degrees of freedom from a starting time to an end time t₀, for example by measuring the real quantities of the real system.

In step S02, at least one degree of freedom f is then selected from the plurality N of degrees of freedom. The selection is random and any degree of freedom can be selected from the plurality N of degrees of freedom, whose state evolution is to be determined. In particular, several degrees of freedom are combined/clustered and used jointly in the further steps. Thereafter, for the at least one selected degree of freedom f, a similarity A_{f} between the selected degree of freedom f and several other degrees of freedom of the plurality N of degrees of freedom of the system is determined for the states previously determined in step S01. In particular, the similarity between each other degree of freedom of the plurality of degrees of freedom is determined and used in the further steps.

Here, the similarity Aₜ describes the similarity in the temporal evolution of the states of the at least one degree of freedom f and the other degree of freedom of the plurality N of degrees of freedom of the real system. Here, a measure of similarity can be used as a quantification of the similarity. In particular, the measure of similarity may be given by a correlation or causality metrics. In particular, a cross correlation p is used for the measure of similarity, where

$$ρ ij = \frac{{\sum }_{t = 1}^{n} ( {x}_{i , t} - {\overline{x}}_{j} ) ( {x}_{j , t} - {\overline{x}}_{j} )}{\sqrt{{\sum }_{t = 1}^{n} {( {x}_{i , t} - {\overline{x}}_{j} )}^{2}} \sqrt{{\sum }_{t = 1}^{n} {( {x}_{j , t} - {\overline{x}}_{j} )}^{2}}}$$

where xᵢ denotes the states for the selected degree of freedom f and xⱼ denotes the states for the respective other degree of freedom of the plurality N of degrees of freedom of the real system. Further, x̅_{i,j} describes the respective mean value. Then, the absolute value of the cross correlation |ρ_{i,j}| can be used as the measure of similarity.

As an alternative, the normalized transinformation or mutual information Iᵢⱼ is used as the measure of similarity with

$${I}_{i j} = \int \int p ( {x}_{i} , {x}_{j} ) log ( \frac{p ( {x}_{i} , {x}_{j} )}{p ( {x}_{i} ) p ( {x}_{j} )} ) d {x}_{j} {dx}_{j} ,$$

where p(xᵢ), p(xᵢ,xⱼ) represent the probability density distributions of the respective degrees of freedom with their states xᵢ or xⱼ.

In any case, the similarity A_{f} is not dependent on a local proximity of the degrees of freedom, so that a correlation or similarity of locally widely spaced degrees of freedom may be given, which may still influence each other, whereby the similarity is caused.

Via the similarity A_{f}, such degrees of freedom in the plurality N of degrees of freedom of the real system can be determined which have a state evolution similar to the selected degree of freedom f. Here, it is possible to determine the similarity also between degrees of freedom concerning different state variables, since only the temporal evolution is of importance. Thereby, a degree of freedom can be characterized, for example, by an oscillation and a degree of freedom similar to that can be characterized by a temperature, with both degrees of freedom showing a similar temporal evolution. Here, it can be assumed that a mutual influence or a correlation exists between the selected degree of freedom f and the degree of freedom with a high similarity. Thus, in step S04, a selection M_{f} of degrees of freedom from the plurality N of degrees of freedom is determined based on the measure of similarity A_{f}. Thus, the selection M_{f} includes the degrees of freedom that have a high similarity to the selected degree of freedom f. Here, the selection M_{f} of degrees of freedom is a subset of the plurality N of degrees of freedom of the entire real system. In particular, M_{f} is therefore smaller than N, and in particular M_{f}<<N. Here, the selection M_{f} comprises in particular less than 100 and preferably less than 10 degrees of freedom. Here, the selection M_{f} includes a suitable number of degrees of freedom such that a determination of the state evolution of, in particular, the measured states for the selected degree of freedom f, is made possible with the computational capacities available, based on the selection Mf according to step S05. The fact that only such degrees of freedom from the plurality N of degrees of freedom of the real system are used, which show a similarity to the selected degree of freedom f, reduces the complexity of the system to be considered when determining the state evolution of, in particular, the measured states for the selected degree of freedom f. This leads to a clear reduction of the demands on the computational capacities, since it is no longer necessary to consider all degrees of freedom of the plurality N of degrees of freedom of the entire system. This is based on the consideration that similar state evolutions for different degrees of freedom of the entire real system are causally related and that thus there is a mutual influence of the degrees of freedom. Here, the similarity or the considered degrees of freedom in the selection M_{f} does not depend on the local proximity of the individual degrees of freedom, but only on the similarity A_{f} determined in step S03.

The determination of the state evolution for the selected degree of freedom f is then performed, for example, using a recurrent neural network, in particular by means of reservoir computing. This method is known, for example, from Mantas Lukoševičius; Herbert Jaeger, “Reservoir computing approaches to recurrent neural network training”, Computer Science Review 2009, 3, 3, pages 127-149. Here, the training of the networks used can be performed based on the states determined for the plurality of N degrees of freedom up to the time t₀ according to step S01 Thus, a state evolution for the selected degree of freedom can be determined, in particular for different starting conditions and/or beyond the time t₀.

FIG. 2 shows another embodiment of the method according to the invention. In the following, only the differences with respect to the method shown in FIG. 1 will be addressed. According to FIG. 2, steps S02 to S04 are repeated in step S05 for each of the degrees of freedom of the plurality N of degrees of freedom, and a respective selection M_{f} of degrees of freedom is then determined for each degree of freedom. Here, according to step S03, the selection M_{f} with f=1, . . . ,N of degrees of freedom may be selected or predetermined to be the same for each of the degrees of freedom f=1, . . . ,N. As an alternative, a different selection M_{f} of degrees of freedom of the plurality N of degrees of freedom can be selected for different selected degrees of freedom f based on an adapted similarity A_{f}. To this end, for each selected degree of freedom f with f=1, . . . ,N, the corresponding similarity A_{f,i} is determined with i=1, . . . ,f−1,f+1, . . . ,N and again f=1, . . . ,N. Here, the determination of the similarity and of the respective selections M_{f} can be performed in parallel. Subsequently, a joint determination of the state evolution is performed, with only the degrees of freedom of the previously determined selection M_{f} being considered for each degree of freedom f. This step of determining the state evolution is performed jointly for the degrees of freedom considered, in particular according to the known method of reservoir computing.

Thus, it is possible to determine the state evolution for the entire real system and, in particular, to determine the state evolution for each of the degrees of freedom of the plurality N of degrees of freedom of the entire real system. Here, a reduction in complexity is caused by the selection, whereby the state evolutions can also be determined for high-dimensional real systems with limited computational capacity. Thus, a characterization of the real system is possible.

In particular, the real system is a thermodynamic system. For example, this may be the weather or weather data. Alternatively, this may be an engine, in particular a rocket engine, an internal combustion engine or the like. As an alternative thereto, the real system are EEG currents detected on a patient. As an alternative thereto, it is a fluidic or a flow system, in which the flow of a fluid is detected in a given topology. As an alternative thereto, it is a movement system for detecting the movement of persons, vehicles, mobile elements in a complex interaction, gas particles in a vacuum, bacteria movement, transport of materials in living cells or the like.

Hereinafter, the invention is described using an engine as a real system. Such an engine has a plurality of degrees of freedom. Each degree of freedom considered is determined by at least one measured variable such as, for example, temperature, pressure, vibration, material mixture concentration (air-fuel mixture ratio) or the like. In particular, a real system comprises a very large number of degrees of freedom. When considering a real system, however, only a number of these degrees of freedom is considered, be it in the context of a measurement (number of considered degrees of freedom limited by the number of sensors) or for the characterization of the system in a state evolution. According to step S01, states or a temporal evolution of the states are detected for each of the degrees of freedom for a plurality of times up to an end time t₀. For this purpose, sensors may be arranged in the engine, for example, which detect the real measured variables at different times and thus generate a time series or state evolution for each of the degrees of freedom of the at least one or a plurality of measured variables. Thereafter, according to step S01, one of these degrees of freedom, represented in particular by one of the sensors installed, is selected as the selected degree of freedom f. Subsequently, the temporal evolution of the states for the selected degree of freedom f is compared to the temporal evolutions of the states of each other degree of freedom, in order to determine therefrom a similarity A_{f} according to step S03. Thereafter, according to step S04, those degrees of freedom, which have a temporal evolution similar to the selected degree of freedom f, are selected from the degrees of freedom of the plurality N of degrees of freedom in the engine. Here, the similarity is not defined by a local proximity of the sensors within the engine. Rather, the similarity is determined based on a similar evolution of the states of the degree of freedom. A similar temporal evolution of the states allows to conclude on a causal linkage or correlation of the degrees of freedom, wherein even distant regions within the engine can influence one another, for example, by transmitted vibrations or the like. Based on the selection M_{f} of degrees of freedom that have a similarity and, in particular, fulfill a criterion with respect to the determined measure of similarity, the state evolution for the selected degree of freedom f is then determined based on the selection M_{f} of degrees of freedom. Thus, the temporal evolution for the selected degree of freedom f can be determined, wherein in particular such degrees of freedom of the selection M_{f} are taken into account that have a causal relationship indicated by the similarity of the temporal evolutions.

Subsequently, according to the embodiment in FIG. 2, the previous steps are repeated to determine the state evolution for each of the degrees of freedom in the entire engine, so as to determine a complete characterization of the engine and of the temporal behavior within the engine. Since only the selection M_{f} of degrees of freedom is considered to determine the state evolution of the measured states of the respective selected degrees of freedom f, the complexity of the real system of the engine is reduced thereby. Therefore, it is no longer necessary to consider all other degrees of freedom of the plurality N of the degrees of freedom of the entire engine to determine the state evolution of the measured states for a selected degree of freedom f. Rather, only such degrees of freedom are considered that have a causal relationship with the selected degree of freedom f. This calculation can be performed with a significantly lower computational capacity.

What is claimed is:

1. A computer-implemented method for determining a state evolution of a real system with a plurality N of degrees of freedom, comprising the following steps:
a) determining states for each of the plurality N of degrees of freedom up to a time t₀, wherein, in particular, the determining of states for each of the plurality N of degrees of freedom is carried out by measuring corresponding state variables of the real system;
b) selecting a degree of freedom f from the plurality N of degrees of freedom;
c) determining a similarity A_{f} between the at least one selected degree of freedom f and plurality of other degrees of freedom of the plurality N of degrees of freedom of the real system for the determined states;
d) determining a selection M_{f} of degrees of freedom from the plurality N of degrees of freedom based on the similarity A_{f}; and
e) determining the state evolution for the at least one selected degree of freedom f based on the selection M_{f} of degrees of freedom.

2. The computer-implemented method according to claim 1, wherein the steps b) to d) are repeated for each degree of freedom of the plurality N of degrees of freedom for determining the degrees of freedom to be considered in determining the state evolution for the entire real system.

3. The computer-implemented method according to claim 1, wherein for the plurality N of the degrees of freedom N is larger than 10, preferably larger than 100 and, particularly preferred, larger than 1000.

4. The computer-implemented method according to claim 1, wherein for the selection M_{f} is less than 1000.

5. The computer-implemented method according to claim 1, wherein the number of the degrees of freedom in the selection M_{f} is determined by a predefined limit value for the similarity.

6. The computer-implemented method according to claim 1, wherein the number of the degrees of freedom in the selection M_{f} is predefined.

7. The computer-implemented method according to claim 1, wherein the similarity is given by a cross correlation or transinformation.

8. The computer-implemented method according to claim 1, wherein the determination of the state evolution is performed using a recurrent neural network, in particular using reservoir computing.

9. The computer-implemented method according to claim 8, wherein the recurrent neural network is trained on the basis of the determined states for each of the plurality of N degrees of freedom up to a time t₀.

10. The computer-implemented method according to claim 1, wherein the real system is a thermodynamic system, EEG currents, a fluidic system, a movement system or a flow system.

11. The computer-implemented method according to claim 1, wherein a control variable is determined to control the real system, depending on the determined state evolution.

12. A device for data processing, comprising a processor and a computer-readable storage medium, the processor being configured to execute the method according to claim 1, and the computer-readable storage medium comprising instructions which, when executed by a computer, cause the same to execute the method according to claim 1.

13. The computer-implemented method according to claim 4, wherein the selection M_{f} is less than 100.

14. The computer implemented method according to claim 13, wherein the selection M_{f} is less than 10.
